(19) United States
(12) Patent Application Publication
(10) Pub. No.: US 2017/0053716 A1
(43) Pub. Date: Feb. 23, 2017

(54) OTP MEMORY INCLUDING TEST CELL ARRAY AND METHOD OF TESTING THE SAME

(71) Applicant: Samsung Electronics Co., Ltd., Suwon-si (KR)

(72) Inventor: Tae-seong Kim, Yongin-si (KR)

(21) Appl. No.: 15/232,201

(22) Filed: Aug. 9, 2016

(30) Foreign Application Priority Data
Aug. 20, 2015 (KR) 10-2015-0117562
Nov. 19, 2015 (KR) 10-2015-0162844

(51) Int. Cl. G11C 29/00; G11C 17/18; G11C 29/04; G11C 17/16

(52) U.S. Cl. CPC G11C 29/76; G11C 17/16; G11C 17/18; G11C 29/78; G11C 29/04

(57) ABSTRACT

In a one-time programmable (OTP) memory and a method of testing the same. The OTP memory includes an OTP cell array comprising OTP cells which are activated by an address received from a source external to the OTP memory and which OTP cells are unprogrammed. A test cell array includes a first test row having unprogrammed first test cells and a second test row having mask-programmed second test cells, and sharing bit lines extending in a column direction with the OTP cell array. The first test cells and second test cells are accessible during testing of the OTP cell array.

### CROSS-REFERENCE TO RELATED APPLICATIONS

This application claims the benefit of Korean Patent Application No. 10-2015-0117562, filed on Aug. 20, 2015, and Korean Patent Application No. 10-2015-0162844, filed on Nov. 19, 2015, in the Korean Intellectual Property Office, the disclosures of which are incorporated herein in their entireties by reference.

### BACKGROUND

In a one-time programmable (OTP) memory device, data may be stored using a plurality of OTP cells, each of which may have an un-programmed state and a programmed state. Data programmed in an OTP cell is retained even when the cell's power supply is removed. An OTP cell that has been programmed a first time cannot be re-programmed a second time. In this manner, a programmed OTP cell is irreversible in state. In some examples, an OTP cell may include a fuse or an anti-fuse and may be electrically programmed. OTP memories have enjoyed long-time use in the field of electronics for permanent storage of information in various applications.

In some cases, it is less efficient to test an OTP memory, as compared to the testing of memories that can be re-programmed multiple times. This is largely due to the fact that the cells of OTP memory cannot be re-programmed. Since testing of a data write/read operation on an OTP memory is accompanied by programming of an OTP cell thereof, the OTP memory that includes an OTP cell programmed during the testing operation may include a storage region in which data cannot be stored by a user.

### SUMMARY

Inventive concepts relate to a one-time programmable (OTP) memory, and more particularly, to an OTP memory including a test cell array and a method of testing the same.

Inventive concepts provide a one-time programmable (OTP) memory, and more particularly, an OTP memory that can be used irrespective of whether it has undergone a test operation, and a method of testing the same.

According to an aspect of the inventive concepts, a one-time programmable (OTP) memory includes an OTP cell array comprising OTP cells which are activated by an address received from a source external to the OTP memory and which OTP cells are unprogrammed. A test cell array includes a first test row having unprogrammed first test cells and a second test row comprising mask-programmed second test cells, and sharing bit lines extending in a column direction with the OTP cell array. The first test cells and second test cells are accessible during testing of the OTP cell array.

According to another aspect of the inventive concepts, a one-time programmable (OTP) memory includes an OTP cell array comprising OTP cells which are unprogrammed. A test cell array shares bit lines extending in a column direction with the OTP cell array, and includes a first test row having unprogrammed first test cells and a second test row including mask-programmed second test cells. A test controller is configured to control programming of the first test cells after the second test cells are read normally, during testing of the OTP cell array.

According to another aspect of the inventive concepts, a one-time-programmable (OTP) memory device includes an array of unprogrammed OTP cells arranged at intersections of, and connected to, rows of externally addressable word lines and columns of bit lines; and an array of test cells connected to the columns of bit lines that are same as those to which the array of OTP cells are connected. The array of test cells includes a first sub-array of test cells arranged at intersections of, and connected to, a first internally addressable word line and the same columns of bit lines, the first sub-array of test cells having first unprogrammed test cells, and a second sub-array of test cells arranged at intersections of, and connected to, a second internally addressable word line and the same columns of bit lines, the second sub-array of test cells having second mask-programmed test cells. A test controller first performs a read operation of the second sub-array of test cells, and, in the event the read operation is successful, next performs a programming operation of the first sub-array of test cells. The first and second internally addressable word lines are inaccessible by an externally applied address of the OTP cells.

### BRIEF DESCRIPTION OF THE DRAWINGS

Embodiments of the inventive concepts will be more clearly understood from the following detailed description taken in conjunction with the accompanying drawings in which:

FIG. 1 is a block diagram of a one-time programmable (OTP) memory device according to an embodiment of the present inventive concepts;

FIGS. 2A and 2B are circuit diagrams of OTP cells according to an embodiment of the present inventive concepts;

FIG. 3 is a block diagram illustrating an example of a test cell array of FIG. 1 and an OTP memory device including the same, according to an embodiment of the present inventive concepts;

FIG. 4 is a flowchart of a method of testing an OTP memory device including a test cell array, according to an embodiment of the present inventive concepts;

FIGS. 5A and 5B are diagrams illustrating examples of the test cell array of FIG. 1 and OTP memory devices respectively including the examples, according to an embodiment of the present inventive concepts;

FIG. 6 is a flowchart of a method of testing an OTP memory device including a test cell array, according to an embodiment of the present inventive concepts;

FIG. 7 is a block diagram of an OTP memory device according to an exemplary embodiment;

FIG. 8 is a diagram illustrating an example of a test cell array of FIG. 7 and an OTP memory device including the example, according to an embodiment of the present inventive concepts;

FIG. 9 is a flowchart of a method of testing an OTP memory device including a test column, according to an embodiment of the present inventive concepts;

FIGS. 10A and 10B are diagrams illustrating examples of an OTP memory device including programmed test columns, according to embodiments of the present inventive concepts;

FIG. 11 is a block diagram of a memory device including an OTP memory according to an embodiment of the present inventive concepts;

FIG. 12 is a block diagram of a computing system including an OTP memory device according to an embodiment of the present inventive concepts;

FIG. 13 is a block diagram of a multimedia system according to an embodiment of the present inventive concepts;

FIG. 14 is a block diagram of a system including an OTP memory device according to an embodiment of the present inventive concepts; and

FIG. 15 is a block diagram of a terminal device including an OTP memory device according to an embodiment of the present inventive concepts.

### DETAILED DESCRIPTION OF EMBODIMENTS

Hereinafter, various embodiments of the inventive concepts will be described in greater detail with reference to the accompanying drawings.

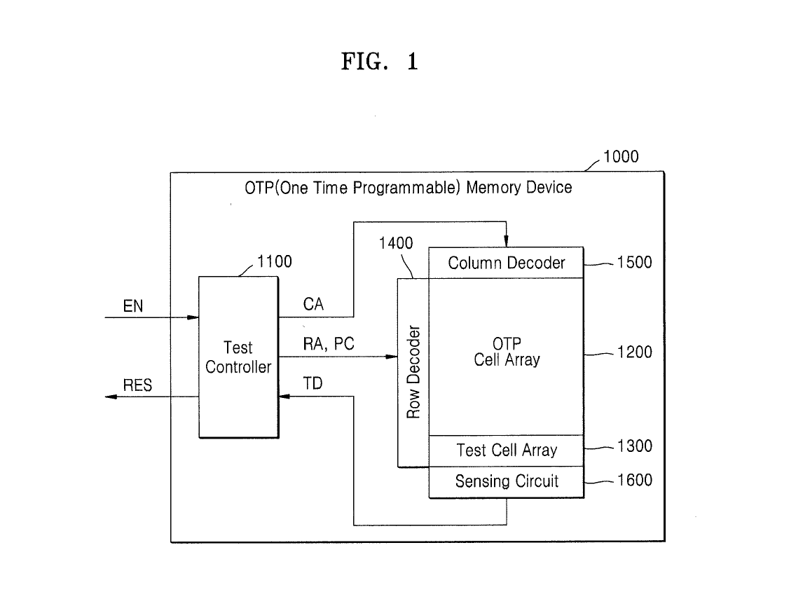

FIG. 1 is a block diagram of a one-time programmable (OTP) memory device 1000 according to an embodiment of the present inventive concepts. In various embodiments, the OTP memory device 1000 may be an independent memory device embodied and packaged a single, discrete, chip. Alternatively, the OTP memory device 1000 may be embodied and packaged as a chip (e.g., a system-on-chip (SoC)) together with different circuits, e.g., a memory, a processing core, input/output circuits, etc. As illustrated in FIG. 1, the OTP memory device 1000 may include a test controller 1100, an OTP cell array 1200, a test cell array 1300, a row decoder 1400, a column decoder 1500, and a sensing circuit 1600.

Referring to FIG. 1, in some embodiments, the OTP memory 1000 may receive a test enable signal EN from an external source instructing the OTP to initiate a test procedure. In addition, the OTP device may output a test result signal RES representing a result of the test procedure to the external source. For example, in some embodiments, the OTP memory 1000 may be tested as a final operation of a process of manufacturing the OTP memory 1000. During the testing of the OTP memory 1000, an activated test enable signal EN may be supplied to the OTP memory 1000. The OTP memory 1000 (particularly, the test controller 1100) may control the testing of the OTP memory 1000 in response to the activated test enable signal EN, and, as a result of the testing operation, output the test result signal RES. During the testing of the OTP memory 1000, a determination can be made as to whether the OTP memory 1000 based on the test result signal RES. In various embodiments, the external source may comprise a circuit or system operating on the same chip or system as the OTP device 1000, or may reside as a separate chip or system in electrical, optical, or wireless communication with the OTP device 1000.

In some embodiments, the test controller 1100 may be constructed and arranged to receive the test enable signal EN, and output the test result signal RES. In addition, the test controller 1100 may control the testing operation of the OTP memory 1000 by controlling the row decoder 1400, the sensing circuit 1600, and the column decoder 1500. Referring to FIG. 1, in some embodiments, the test controller 1100 may transmit a row address RA and a program control signal PC to the row decoder 1400, may transmit a column address CA to the column decoder 1500, and may receive resulting test data TD from the sensing circuit 1600.

The OTP cell array 1200 may include a plurality of OTP cells arranged in a plurality of rows and a plurality of columns. The plurality of OTP cells may each have one of two states: an unprogrammed state; or a programmed state. The plurality of OTP cells may store data corresponding to the unprogrammed state or the programmed state thereof. Also, the plurality of OTP cells may have a plurality of programmed states to store data corresponding to a plurality of bits. Hereinafter, it will be described that an OTP cell has one programmed state, an unprogrammed OTP cell stores a binary value of ‘0’, and a programmed OTP cell stores a binary value of ‘1’. However, the inventive concepts are not limited thereto. For example, in other embodiments, an unprogrammed OTP cell can store a binary value of ‘1’, and a programmed OTP cell can store a binary value of ‘0’.

The test cell array 1300 may share a plurality of bit lines with the OTP cell array 1200, and may include a plurality of test cells. In some embodiments, the plurality of OTP cells of the OTP cell array 1200 are accessible in response to an address received from a unit external to the OTP memory 1000, whereas the plurality of test cells of the test cell array 1300 are accessible within the OTP memory 1000. In other words, in some embodiments, the plurality of test cells of the test cell array 1300 are accessible under the control of the test controller 1100 of the OTP memory 1000.

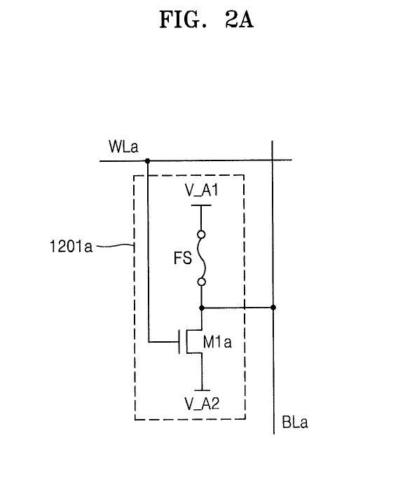

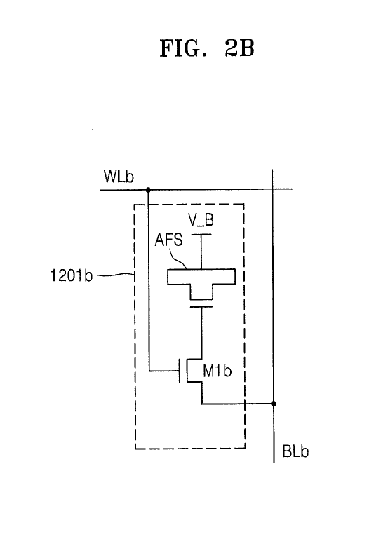

As described herein with reference to FIGS. 2A and 2B, an OTP cell of the OTP cell array 1200, once programmed, cannot be programmed a second time. This is generally the type of operation that defines a one-time-programmable cell or device. As a result, there are certain inefficiencies in connection with the testing of OTP memory 1000. Accordingly, the OTP memory 1000, the write operation of which is tested by programming an OTP cell thereof may include a memory region that is not accessible for use by a user of the OTP memory 1000. Consequently, some of a plurality of the OTP cells of the OTP memory device may be consumed for the testing operation of the OTP memory, and otherwise unavailable to use during normal operation of the OTP device 1000.

Returning to FIG. 1, according to an embodiment of the present inventive concepts, an OTP memory device 1000 may include the test cell array 1300 having a plurality of test cells, and may be passed for use by a user upon the OTP memory 1000 passing testing thereof. In some embodiments, the testing is performed by writing data to, or programming, certain test cells. After the OTP memory device 1000 passes testing, it is thus determined to be a device having normal operation. Accordingly, it may include the entire OTP cell array 1200, the entire data regions of which are available to a user. Thus, in this manner, the productivity of the OTP memory 1000 may be improved, since operational data cells are not consumed by the testing operation.

The row decoder 1400 may operate to activate at least one among a plurality of word lines connected to a plurality of rows of the OTP cell array 1200 according to the row address RA received from the test controller 1100. Also, the row decoder 1400 may apply a program voltage to at least one among the plurality of rows of the OTP cell array 1200 according to the program control signal PC received from the test controller 1100. As described with reference to FIGS. 2A and 2B herein, the program voltage may be used to open both ends of a fuse, in other words, open the fuse, included in an OTP cell or, alternatively, to close both ends of an anti-fuse, in other words, close the fuse, included in the OTP cell. The OTP cell may be selectively programmed on the basis of the program voltage and a voltage of a bit line.

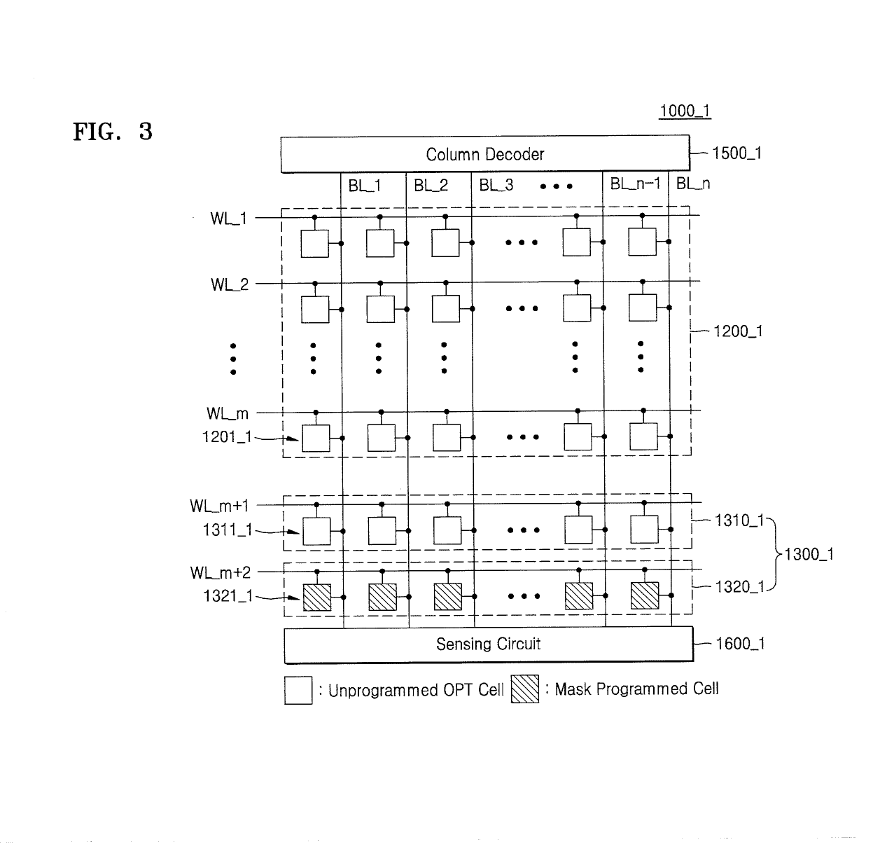

As illustrated in FIG. 1, the row decoder 1400 may operate to activate at least one among the plurality of word lines connected to the plurality of rows of the OTP cell array 1200. In addition, the row decoder 1400 may operate to also activate a word line connected to at least one row of the test cell array 1300 according to the row address RA. In addition, the row decoder may operate to apply the program voltage to least one among the plurality of rows of the test cell array 1300 according to the program control signal PC. As described herein with reference to FIG. 3, and other examples herein, the test cell array 1300 may include, as test cells, a mask-programmed cell, or an unprogrammed cell, or, in some embodiments, both types of cells.

In some embodiments, the column decoder 1500 may apply a ‘program allow’ voltage or a ‘program inhibit’ voltage to each of a plurality of bit lines connected to the plurality of columns of the OTP cell array 1200 and the test cell array 1300, according to the column address CA received from the test controller 1100. For example, the column decoder 1500 may apply the ‘program allow’ voltage or the ‘program inhibit’ voltage to bit lines connected to either OTP cells included in a selected row according to the column address CA, or connected to test cells, so that the OTP cells or the test cells may be programmed or prevented from being programmed when the program voltage is applied thereto by the row decoder 1400. Thus, in this manner, the OTP cells included in the selected row, or the test cells, may be selectively programmed.

Continuing to refer to FIG. 1, the sensing circuit 1600 may be connected to the plurality of bit lines shared between the OTP cell array 1200 and the test cell array 1300. The sensing circuit is operational to sense voltages or currents of the plurality of bit lines to amplify signals output from the OTP cells or the test cells via the plurality of bit lines. Thus, in this manner, the sensing circuit 1600 operates to output data stored in the OTP cells or the test cells. In particular, during testing of the OTP memory 1000, the sensing circuit 1600 may output test data TD by amplifying signals output via the plurality of bit lines, and provide the test data TD to the test controller 1100.

FIGS. 2A and 2B are circuit diagrams of OTP cells 1201a and 1201b according to embodiments of the present inventive concepts. In detail, FIG. 2A illustrates an OTP cell 1201a which is a fuse-type OTP cell, and FIG. 2B illustrates an OTP cell 1201b which is an anti-fuse type OTP cell. A fuse or anti-fuse, the state of which can be changed by application of an electrical signal, may be referred to generally as an ‘electrically programmable fuse (eFUSE)’.

Referring to FIG. 2A, the OTP cell 1201a may be connected to a word line WLa and a bit line BLa of the OTP memory device 1000. The OTP cell 1201a may include a fuse FS and a transistor M1a connected to the fuse FS. The fuse FS is a device, the terminals of which are changed to an open state or a high resistance state when a high voltage is applied thereto. For example, the fuse FS may have a high resistance value due to electro-migration occurring in the fuse FS when a high voltage is applied thereto. That is, when the column decoder 1500 applies a low voltage (e.g., a ground voltage) to the bit line BLa and the row driver 1400 increases a voltage V_A1, the terminals of the fuse may become open and the state of the fuse FS may be changed to the high-resistance state.

When the word line WLa is activated and an appropriate voltage is applied to the voltage V_A1 so as to read data stored in the OTP cell 1201a, a voltage of the bit line BLa or the amount of current output via the bit line BLa may vary according to the state of the fuse FS. The sensing circuit 1600 may sense the data stored in the OTP cell 1201a on the basis of such a voltage or current difference.

Referring to FIG. 2B, the OTP cell 1201b may be connected to a word line WLb and a bit line BLb of the OTP device 1000. The OTP cell 1201b may include an anti-fuse AFS and a transistor M1b connected to the anti-fuse AFS. The anti-fuse AFS is a device, the terminals of which are changed to a closed state or a low-resistance state when a high voltage is applied thereto. For example, when a high voltage such as a breakdown voltage is applied to the terminals of the anti-fuse AFS which are separated by a gate oxide film, the gate oxide film may become broken, shorting the terminals. As a result, the resulting anti-fuse AFS may be placed in a low-resistance state. That is, when the column decoder 1500 applies a low voltage (e.g., the ground voltage) to the bit line BLb and the row driver 1400 increases a voltage V_B to the breakdown voltage, the state of the anti-fuse AFS may be changed to the low-resistance state.

The OTP cells 1201a and 1201b illustrated in FIGS. 2A and 2B are merely examples, and an OTP memory according to an exemplary embodiment may include OTP cells having a different structure from those of the OTP cells 1201a and 1201b of FIGS. 2A and 2B. As described herein for purposes of discussion, OTP memory devices according to exemplary embodiments include anti-fuse type OTP cells; however, the inventive concepts are not limited thereto, and other structures of OTP cells may apply.

FIG. 3 is a diagram illustrating a test cell array 1300_1, such as the test cell array 1300 of FIG. 1, and an OTP memory device 1000_1 including the same, according to an embodiment of the present inventive concepts. Also included is an OTP operational cell array 1200_1. As described above with reference to FIG. 1, the test cell array 1300_1 may share bit lines with the OTP operational cell array 1200_1, and may include a plurality of test cells.

Referring to FIG. 3, the OTP cell array 1200_1 may include a plurality of unprogrammed OTP cells 1201_1. That is, the OTP cells 1201_1 of the OTP cell array 1200_1 may each include an anti-fuse, the terminals of which have an open state (or a high-resistance state). Each of the OTP cells 1201_1 may be connected to one of a plurality of word lines WL_1 to WL_m extending in a row direction and arranged in a column direction, and one of a plurality of bit lines BL_1 to BL_n extending in the column direction and arranged in the row direction. Although not shown, the OTP cell array 1200_1 may further include a test controller and a row decoder, such as the test controller 1100 and the row decoder 1400 of FIG. 1.

As described above with reference to FIG. 1, the OTP cells 1201_1 may be accessible in response to an address received from a source external to the OTP memory 1000_1. For example, as illustrated in FIG. 3, when the row-direction length of data output from the OTP memory 1000_1 is n-bits long corresponding to the number of bit lines, the OTP memory 1000_1 may receive a k-bit address signal satisfying 2=rm and activate one of m word lines according to the k-bit address signal. In the present disclosure, when ‘m’ and ‘n’ are positive integers, it is assumed that the OTP cell array 1200_1 includes m×n OTP cells (e.g., 32×32 OTP cells) that are accessible by a source external to the OTP cell array 1200_1.

Continuing to refer to FIG. 3, the test cell array 1300_1 may include a first test row 1310_1 including first unprogrammed test cells 1311_1. According to an exemplary embodiment, the first test cells 1311_1 of the first test row 1310_1 may have the same structure as of the OTP cells 1201_1 of the OTP cell array 1200_1 and may be programmed during testing of the OTP memory 1000_1. A program operation (or a write operation) of the OTP memory 1000_1 may be tested by programming the first test cells 1311_1 and subsequently reading data from the programmed first test cells 1311_1. Thus, a determination can be made as to whether the various components of the OTP memory device, such as the row decoder, the column decoder, the sensing circuit, the bit lines, etc. of the OTP memory 1000_1 are defective or whether they are operating properly.

In some embodiments, the test cell array 1300_1 may include a second test row 1320_1 including mask-programmed second test cells 1321_1. The second test cells 1321_1 may be processed to correspond to the programmed state or the unprogrammed state of the OTP cells 1201_1 during manufacture of the OTP memory 1000_1. For example, the second test cells 1321_1 may have a layout having a structure corresponding to the programmed state of the OTP cells 1201_1, i.e., an anti-fuse AFS type, the terminals of which have a closed state or a low-resistance state. That is, the second test cells 1321_1 may have the same layout as the OTP operational cells 1201_1 except for the anti-fuse AFS and may include a conductor (e.g., a metal) as the structure corresponding to the anti-fuse AFS OTP of the cells 1201_1. As another example, the second test cells 1321_1 may have a layout having a structure corresponding to the unprogrammed state of the OTP cells 1201_1, i.e., an anti-fuse AFS, the both ends of which have an open state or a high-resistance state. That is, the second test cells 1321_1 may have the same layout as the OTP cells 1201_1 except for the anti-fuse AFS, and may include an insulator as the structure corresponding to the anti-fuse AFS OTP of the cells 1201_1. Thus, a read operation of the OTP memory device 1000_1 may be tested by reading data stored in the second test cells 1321_1. Thus, a determination can be made as to whether the various components of the memory device 1000, including the row decoder, the column decoder, the sensing circuit 1600, the bit lines, etc. of the OTP memory device 1000_1 are defective or whether they are operating properly.

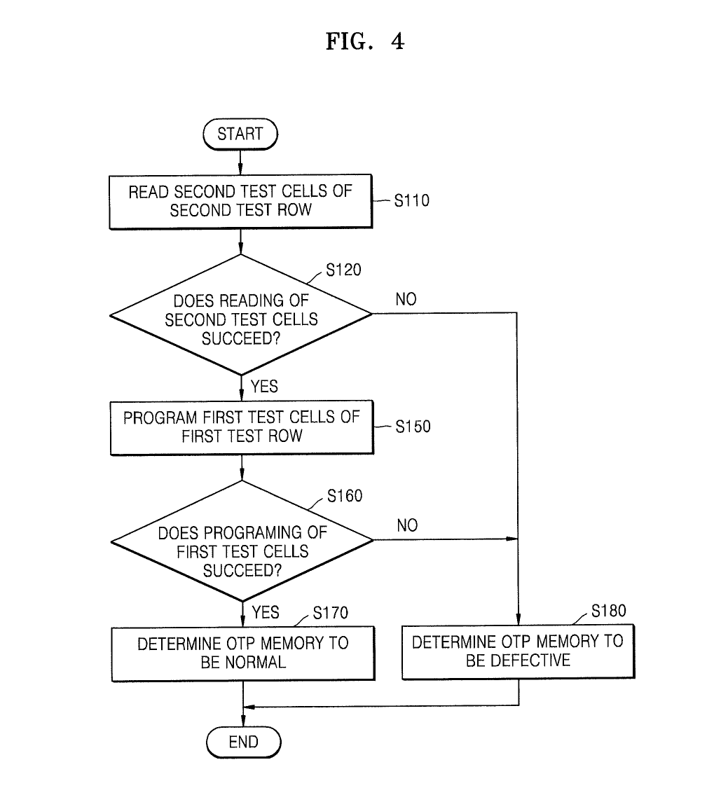

FIG. 4 is a flowchart of a method of testing an OTP memory device including a test cell array, according to an embodiment of the present inventive concepts. As described above with reference to FIG. 1, the test controller 1100 may test the OTP memory 1000 according to a test enable signal EN. The performing of operations S110 to S180 of the method of FIG. 4 may be controlled by the test controller 1100 of FIG. 1. In some embodiments, the test controller 1100 may output a test result signal RES representing a test result to the external source external to the OTP memory device 1000. In detail, FIG. 4 is a flowchart of a method of testing the OTP memory device 1000_1 of FIG. 3. As illustrated in FIG. 4, the method of testing the OTP memory device 1000_1 may include operations S110 to S180. The method of FIG. 4 will be described with reference to FIG. 3 herein.

Referring to FIG. 4, in operation S110, the states of the second test cells 1321_1 of the second test row 1320_1 may be read. For example, the second test cells 1321_1 may be mask-programmed to correspond to the OTP operational cells 1201_1 programmed during manufacture of the OTP memory 1000_1, i.e., to store a binary value of ‘1’.

In operation S120, a determination can be made as to whether the reading of the second test cells 1321_1 of the second test row 1320_1 succeeds or whether the reading fails. As described above, since the second test cells 1321_1 have been mask-programmed to a state known to the manufacturer of the OTP memory 1000_1, the determination of whether the reading operation of the second test cells 1321_1 of the second test row 1320_1 is successful can be made on the basis of test data TD output from the sensing circuit 1600 during reading of data from the mask-programmed second test cells 1321_1. For example, if all the second test cells 1321_1 are mask-programmed to store a binary value of ‘1’, the reading operation of the second test cells 1321_1 may be determined to be a failure when the test data TD output from the sensing circuit 1600 by accessing the second test cells 1321_1 includes a bit which is not a binary value of ‘1’. In operation S180, if the reading operation of the second test cells 1321_1 fails, the OTP memory 1000_1 may be determined to be defective. Alternatively, if the reading operation of the second test cells 1321_1 is determined to have succeeded, the process continues to operation S150.

In operation S150, if the reading operation of the second test cells 1321_1 succeeds, the first test cells 1311_1 of the first test row 1310_1 may be programmed. As described herein with reference to FIG. 3, the first test cells 1311_1 may have the same structure, i.e., the same layout, as unprogrammed OTP cells 1201_1. During the testing of the OTP memory 1000_1, the first test cells 1311_1 may be programmed and thus the proper programming of the OTP memory device 1000_1 may be tested in connection with operation S150 and subsequent operation S160. The OTP memory device 1000_1 thereby determined to be normal as a result of testing the OTP memory 1000_1 by programming the first test cells 1311_1 of the test cell array 1300_1 can this be provided to a user. In other words, the operational OTP memory device 1000 can be provided to a user with all OTP operational cells 1201_1 of the OTP cell array 1200_1 available to the user for programming; none of the operational cells have been consumed by the testing operation.

In operation S160, a determination can be made as to whether the programming of the first test cells 1311_1 of the first test row 1310_1 succeeds or not. That is, a determination of whether the programming of the first test cells 1311_1 succeeds may be accomplished by reviewing the test data TD obtained by a reading operation of data stored in the first test cells 1311_1. For example, when all the first test cells 1311_1 are programmed to store a binary value of ‘1’ in operation S150 and where the test data TD includes a bit which is not a ‘1’ in operation S160, the programming of the first test cells 1311_1 may be determined to be a failure. When the programming of the first test cells 1311_1 fails, the OTP memory 1000_1 may be determined to be defective in connection with operation S180. Alternatively, in connection with operation S170, when the programming of the first test cells 1311_1 succeeds, the OTP memory 1000_1 may be determined to be normal.

As illustrated in FIG. 4, the defective condition of an OTP memory 1000_1 can be determined at an early stage by first reading the second test row 1320-1 and determining whether the reading operation thereof succeeds. That is, when an element of the OTP memory 1000_1 related to the read operation is defective, the OTP memory 1000_1 may be determined to be defective in operation S120 and subsequent operation S180 in an early stage. Also, in this case, in the OTP memory 1000_1, programming and reading of the first test cells 1311_1 is not needed. Thus, the defective state of the OTP memory may be rapidly determined, without the need for performing a testing operation on the OTP memory operational cells. Accordingly, it is possible to reduce the amount of time required to test one or more OTP memory devices. Furthermore, as described above, when the OTP memory 1000_1 is determined by the testing procedure to be “normal”, only those test cells (i.e., first test cells) of the test cell array 1300_1 have been subjected to the programming operation, and thus, the operational OTP memory cells 1200_1 of the OTP memory device 1000_1 may be fully available to a user for the storage of user data. Accordingly, the productivity of the resulting OTP memory device 1000_1 may be improved.

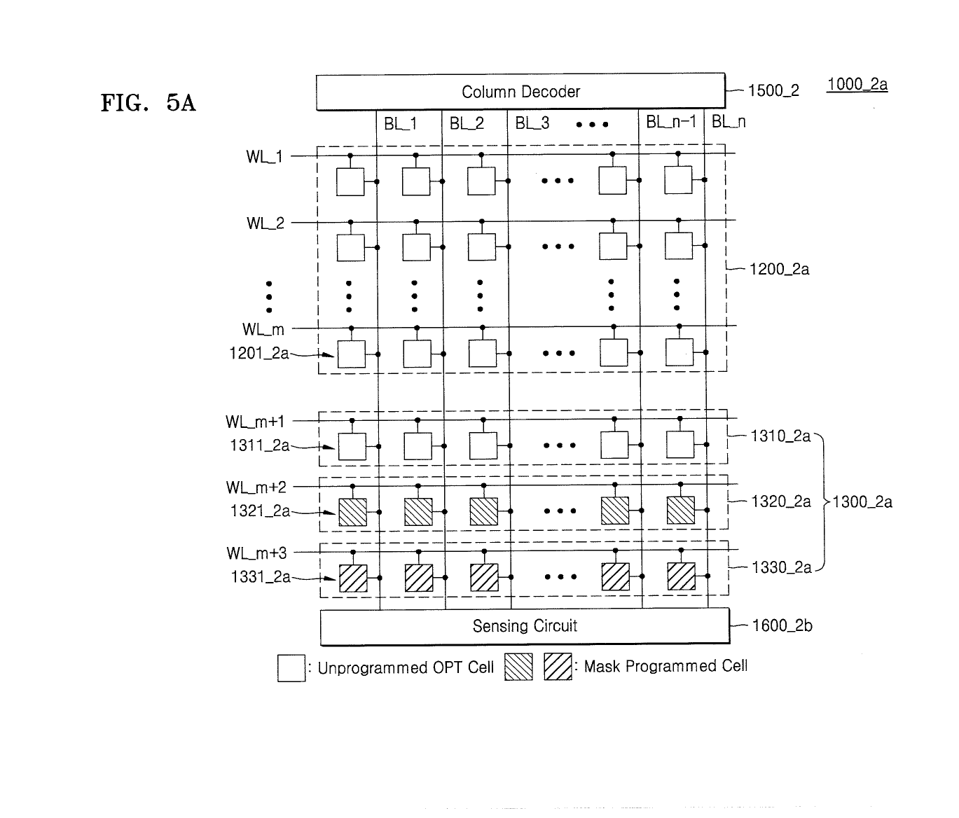

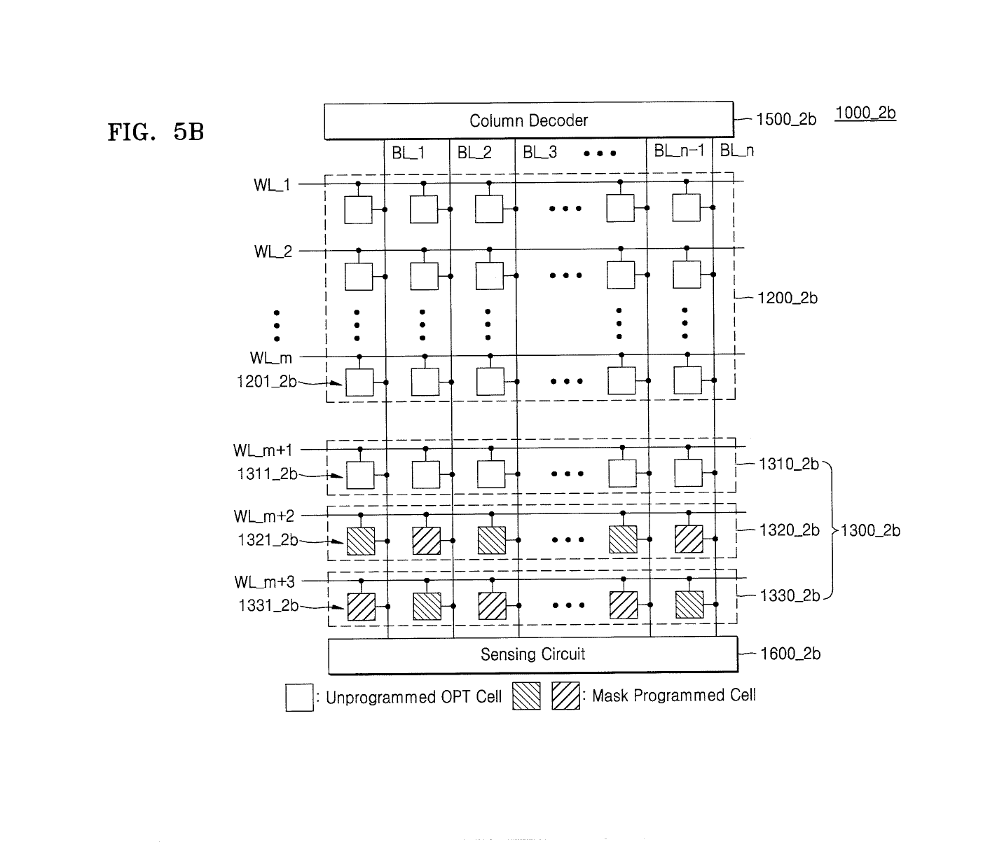

FIGS. 5A and 5B are diagrams illustrating test cell arrays 1300_2a and 1300_2b which are examples of the test cell array 1300 of FIG. 1 and OTP memory devices 1000_2a and 1000_2b respectively including the examples, according to exemplary embodiments. In detail, in FIGS. 5A and 5B, each of the test cell arrays 1300_2a and 1300_2b may include two or more rows including mask-programmed test cells.

Referring to FIGS. 5A and 5B, OTP cell arrays 1200_2a and 1200_2b may respectively include OTP operational cells 1201_2a and 1201_2b which are not subjected to a programming operation during testing. The OTP cells 1201_2a and 1201_2b may be connected to a plurality of word lines WL_1 to WL_m and a plurality of bit lines BL_1 to BL_n as described herein. Although not shown, each of the OTP cell arrays 1200_2a and 1200_2b may further include a test controller and a row decoder such as the test controller 1100 and the row decoder 1400 of FIG. 1.

Referring to FIG. 5A, the test cell array 1300_2a may include a first test row 1310_2a having unprogrammed first test cells 1311_2a, a second test row 1320_2a having mask-programmed second test cells 1321_2a, and a third test row 1330_2a having mask-programmed third test cells 1331_2a. That is, the test cell array 1300_2a of FIG. 5A may include two or more rows (e.g., the rows 1320_2a and 1330_2a) having mask-programmed test cells. This is in comparison to the test cell array 1300_1 of FIG. 3 which has only one row 1320_1 of mask-programmed test cells.

According to an exemplary embodiment, in the second and third test rows 1320_2a and 1330_2a, a second test cell and a third test cell connected to the same bit line may be mask-programmed to have different states, i.e., to have different data. For example, as illustrated in FIG. 5A, the second test cell and the third test cell connected to a first bit line BL_1 may be mask-programmed to respectively store ‘1’ and ‘0’. Thus, during testing of the OTP memory 1000_2a, reading of data that may be stored in the OTP cells 1201_2a, i.e., ‘1’ and ‘0’, may be tested. For example, in an OTP memory from which only ‘1’ is sensed due to a failure occurring in a bit line or the like, a test cell storing ‘0’ may be read to detect the failure. In the embodiment of FIG. 5A, the second test cells 1321_2a included in the second test row 1320_2a may be mask-programmed to store the same data, i.e., ‘1’ and the third test cells 1331_2a included in the third test row 1330_2a may be mask-programmed to store the same data, i.e., ‘0’. Alternatively, in the embodiment of FIG. 5A, the second test cells 1321_2a included in the second test row 1320_2a may be mask-programmed to store the same data, i.e., ‘0’ and the third test cells 1331_2a included in the third test row 1330_2a may be mask-programmed to store the same data, i.e., ‘1’.

Referring to FIG. 5B, the test cell array 1300_2b may include a first test row 1310_2b having unprogrammed first test cells 1311_2b, a second test row 1320_2b having mask-programmed second test cells 1321_2b, and a third test row 13302b having mask-programmed third test cells 1331_2b, similar to the test cell array 1300_2a of FIG. 5A.

Similar to the embodiment of FIG. 5A, in the second and third test rows 1320_2b and 1330_2b, a second test cell and a third test cell connected to the same bit line may be mask-programmed to have different states, i.e., to have different data. Also, in the embodiment of FIG. 5B, each of the second test cells 1321_2b included in the second test row 1320_2a may store different data, i.e., ‘1’ or ‘0’, and each of the third test cells 1331_2b included in the third test row 1330_2a may store different data, i.e., ‘1’ or ‘0’. In other words, a data pattern of 010101 . . . 01 may be stored in the test cells 1321_2b of the second test row 1320_2b and a complementary data pattern of 101010 . . . 10 may be stored in the test cells 1331_2b of the third test row 1330_2b.

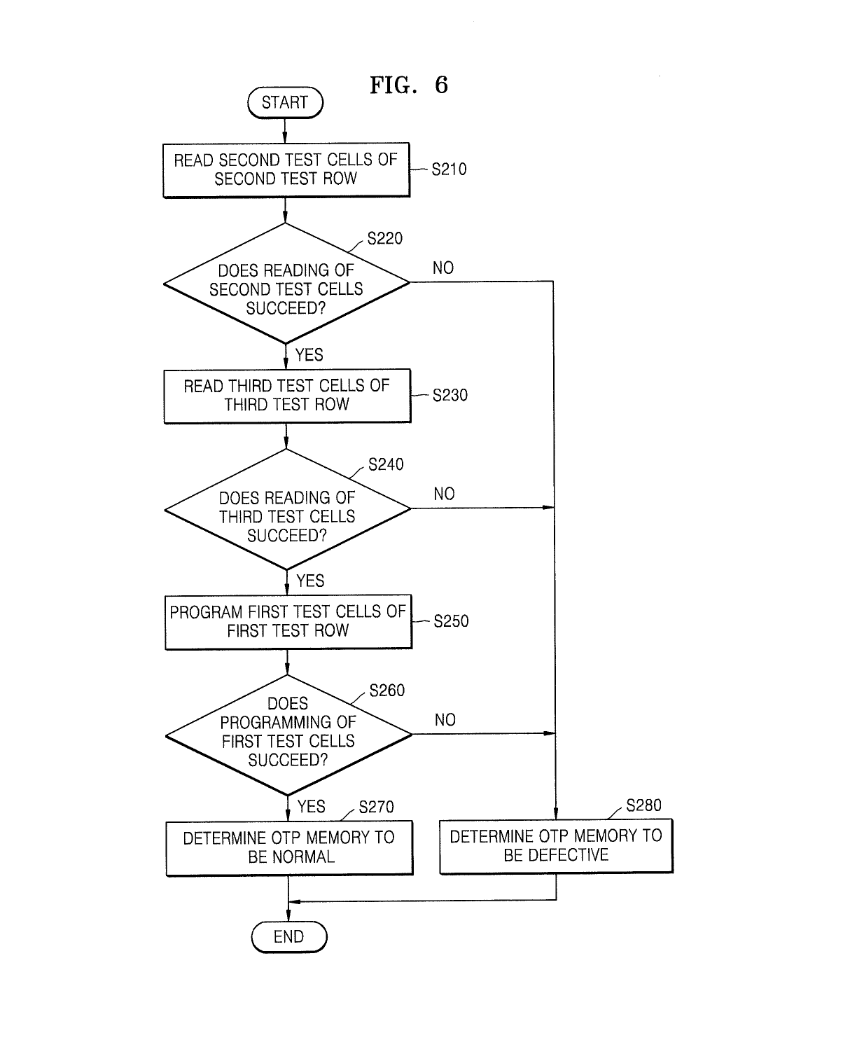

FIG. 6 is a flowchart of a method of testing an OTP memory including a test cell array, according to an exemplary embodiment of the present inventive concepts. Performing of the method of FIG. 6 may be controlled by the test controller 1100. In detail, FIG. 6 is a flowchart of a method of testing the OTP memory 1000_2a or 1000_2b of the type illustrated in FIG. 5A or 5B. The method of FIG. 6 will be described with reference to FIG. 5A below. As illustrated in FIG. 6, the method of testing the OTP memory 1000_2a may include operations S210 to S280.

Referring to FIG. 6, in operation S210, the second test cells 1321_2a of the second test row 1320_2a may be read. Next, in operation S220, a determination can be made as to whether the reading of the second test cells 1321_2a has succeeded. As illustrated in FIG. 5A, the second test cells 1321_2a may be mask-programmed to store a value of ‘1’ during manufacture of the OTP memory 1000_2a. When test data TD obtained by accessing the second test cells 1321_2a includes a value of ‘0’, the reading of the second test cells 1321_2a may be determined to be a failure. In operation S280, when the reading of the second test cells 1321_2a fails, the OTP memory 1000_2a may be determined to be defective. This determination as defective can be made absent the need for performing a test program operation; leading to a more efficient testing procedure.

In operation S230, when the reading of the second test cells 1321_2a succeeds, the third test cells 1331_2a of the third test row 1330_2a may be read. Next, in operation S240, whether the reading of the third test cells 1331_2a succeeds may be determined. As illustrated in FIG. 5A, the third test cells 1331_2a may be mask-programmed to store ‘0’ during manufacture of OTP memory 1000_2a, and the reading of the third test cells 1331_2a may be determined to be a failure when test data TD obtained by accessing the third test cells 1331_2a includes ‘1’. In operation S280, when the reading of the third test cells 1331_2a fails, the OTP memory 1000_2a may be determined to be defective. Alternatively, the mask programming can be made to store a data value of ‘1’, and failure can be determined in the event the read data includes a ‘0’.

In operation S250, when the reading of the third test cells 1331_2a succeeds, the first test cells 1311_2a of the first test row 1310_2a may be programmed. Next, in operation S260, a determination can be made as to whether the programming of the first test cells 1311_2a succeeds. As illustrated in FIG. 5A, the first test cells 1311_2a may have the same layout as the OTP cells 1201_1a which are not programmed. When the first test cells 1311_2a are programmed to store ‘1’ and test data TD obtained by accessing the programmed first test cells 1311_2a includes ‘0’, the programming of the first test cells 1311_2a may be determined to be a failure. In operation S280, when the programming of the first test cells 1311_2a may be determined to be a failure, the OTP memory 1000_2a may be determined to be defective. Alternatively, when the first test cells 1311_2a are programmed to store ‘0’ and test data TD obtained by accessing the programmed first test cells 1311_2a includes ‘1’, the programming of the first test cells 1311_2a may be determined to be a failure. In operation S280, when the programming of the first test cells 1311_2a may be determined to be a failure, the OTP memory 1000_2a may be determined to be defective. In operation S270, when the programming of the first test cells 1311_2a is determined to be a success, the OTP memory 1000_2a may be determined to be normal.

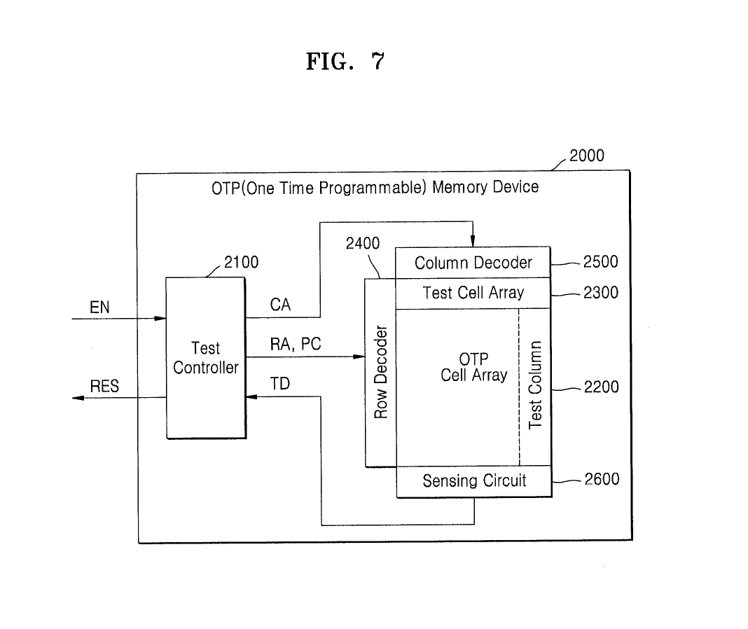

FIG. 7 is a block diagram of an OTP memory device 2000 according to an exemplary embodiment of the present inventive concepts. Similar to the embodiment of FIG. 1, the OTP memory device 2000 of FIG. 7 may include a test controller 2100, an OTP cell array 2200, a test cell array 2300, a row decoder 2400, a column decoder 2500, and a sensing circuit 2600.

According to an exemplary embodiment, the OTP cell array 2200 may be positioned between the test cell array 2300 and the sensing circuit 2600. That is, as illustrated in FIG. 7, the test cell array 2300 and the sensing circuit 2600 may be respectively located on opposed sides of the OTP cell array 2200. When a test cell included in the test cell array 2300 is read, a signal output from the test cell may propagate across the OTP cell array 2200 and then arrive at the sensing circuit 2600. Thus, the entire length of each of bit lines in the OTP cell array 2200 may be tested.

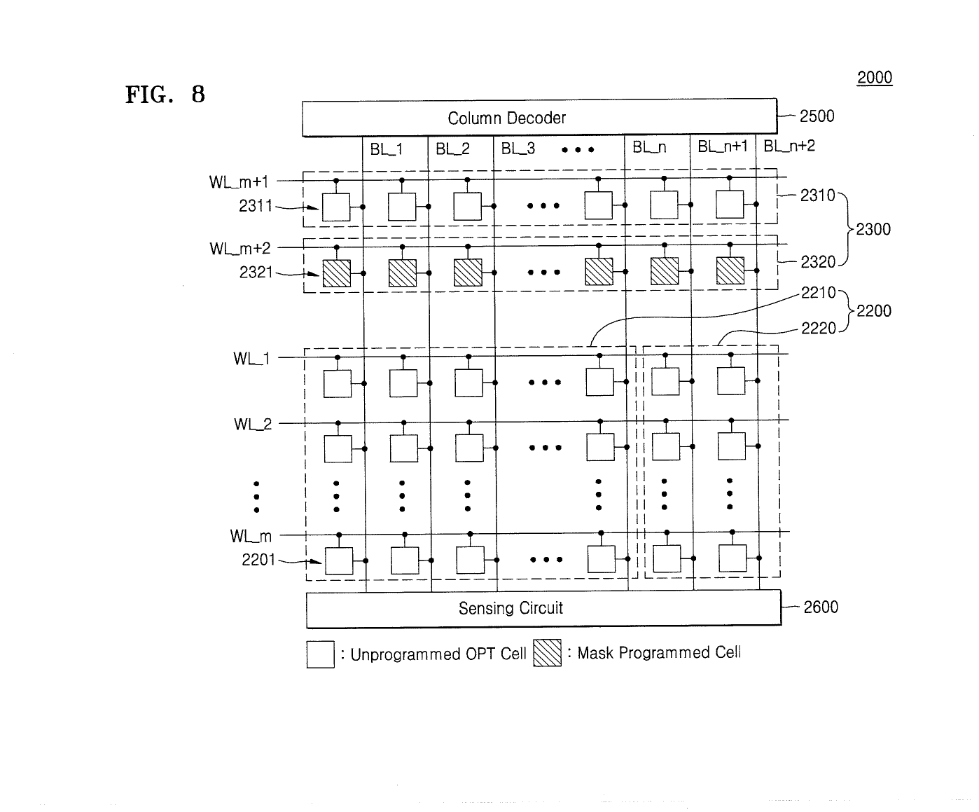

According to an exemplary embodiment, the OTP cell array 2200 may include at least one test column. As illustrated in FIG. 7, the at least one test column may be located on a side surface of the OTP cell array 2200 opposite to the side surface of the OTP cell array 2200 on which the row decoder 2400 is located. OTP cells included in the at least one test column may be selected by a word line activated according to an address provided from the source external to the OTP memory device 2000. At the same time, data read by the signals output from the OTP cells included in the at least one test column via bit lines is not output to back to the source external to OTP memory device 2000. That is, referring to FIG. 3, the number of the bit lines included in the OTP device may be greater than ‘n’. The operation of the test cell array 2300 and the at least one test column of FIG. 7 will be described in detail with reference to FIGS. 8 to 10B herein.

FIG. 8 is a diagram illustrating an example of the test cell array 2300 of FIG. 7 and an OTP memory device 2000 including the example, according to an embodiment of the present inventive concepts. As described above with reference to FIG. 7, an OTP cell array 2200 may be positioned along the bit lines BL_n between a test cell array 2300 and a sensing circuit 2600 of the OTP memory device 2000. The OTP cell array 2200 may include at least one test column on a side surface of the OTP cell array 2200 opposite a position of the row driver 2400 along the word lines WL_m thereof.

Referring to FIG. 8, the test cell array 2300 may include a first test row 2310 including unprogrammed first test cells, and a second test row 2320 including programmed second test cells. For example, the second test row 2320 can include mask-programmed cells as described herein. According to an exemplary embodiment, the test cell array 2300 may further include a test row including unprogrammed test cells and/or a test row including programmed test cells. As illustrated in FIG. 8, the OTP cell array 2200 may be located between the sensing circuit 2600 for sensing signals of bit lines BL_1 to BL_n+2 and the test cell array 2300. Thus, a process of reading the test cells included in the test cell array 2300 may include sensing a signal passing through the bit lines BL_1 to BL_n+2 crossing the OTP cell array 2200 by the sensing circuit 2600. In this manner, the entire length of each of the bit lines BL_1 to BL_n+2 between the column decoder 2500 and the sensing circuit 2600 may be tested by the testing operation.

Referring to FIG. 8, the OTP cell array 2200 may be programmed by a user, and include a user region 2210 having m×n OTP cells for storing data to be output to the outside of the OTP memory 2000, and test columns 2220. The two test columns 2220 may include a plurality of OTP cells which are connected to word lines WL_1 to WL_m and which are not programmed. That is, some of the plurality of OTP cells 2201 included in the OTP cell array 2200 may be used for the purpose of testing word lines, etc. Thus, the OTP memory 2000 may include (n+2) bit lines BL_1 to BL_n+2, the total number of which is greater by ‘n’ than the width of data output available to the source external to the OTP memory 2000 (or a multiple of the width of the data). That is, even if the OTP operational cells included in the test columns 2220 are programmed during testing of the OTP memory 2000, the OTP memory 2000 when it is determined to be normal may be provided to a user. Similar to the test cell array 2300, since the test columns 2200 are located on a side of the OTP cell array 2200 opposite to the side of the OTP cell array 2200 on which the row decoder 2400 is located, the operation of the entire length of each of the word lines WL_1 to WL_m crossing the OTP cell array 2200 may be tested.

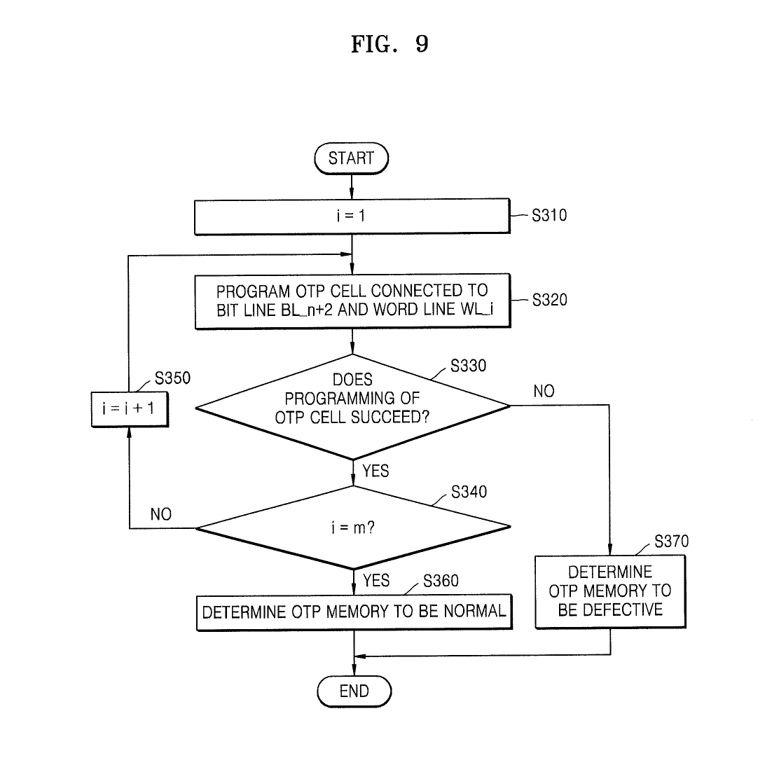

FIG. 9 is a flowchart of a method of testing an OTP memory including a test column, according to an exemplary embodiment. In some embodiments, the performing of the method of FIG. 9 may be controlled by the test controller 2100. In detail, FIG. 9 is a flowchart of a method of testing the OTP memory 2000 of FIG. 8. The method of FIG. 9 will be described with reference to FIG. 8 herein. As illustrated in FIG. 9, the method of testing the OTP memory 2000 may include operations S310 to S370.

Referring to FIG. 9, in operation S310, in some embodiments, a variable i may be set to a value of ‘1’. In the flowchart of FIG. 9, the variable i may represent one of the plurality of word lines WL_1 to WL_m.

In operation S320, an OTP cell connected to the bit line BL_n+2 and the word line WL_i may be programmed. That is, an OTP cell connected to the word line WL_i and included in a test column located at an edge of the OTP cell array 2200 may be programmed.

In operation S330, a determination can be made as to whether the programming of the OTP cell connected to the bit line BL_n+2 and the word line WL_i succeeds. That is, whether the programming of the OTP cell connected to the bit line BL_n+2 and the word line WL_i succeeds may be determined by checking a bit included in test data TD output from the sensing circuit 2600, e.g., a most significant bit (MSB) or a least significant bit (LSB), by sensing a signal of the bit line BL_n+2 by accessing the OTP cell connected to the bit line BL_n+2 and the word line WL_i. In operation S370, when programming of the OTP cell included in the test column fails, the OTP memory may be determined to be defective.

In operation S340, when the programming of the OTP cell included in the test column succeeds, whether the variable i is equal to ‘m’ may be determined. That is, whether testing of the OTP cell connected to the last word line WL_m succeeds may be determined. Next, in operation S350, when the variable i is less than ‘m’, the variable i may be increased by ‘1’. Next, in operation S320, an OTP cell connected to a subsequent word line may be programmed. In operation S360, when the variable i is equal to ‘m’, the OTP memory 2000 may be determined to be normal.

In an exemplary embodiment, testing of the OTP memory 2000 by using the test cell array 2300 and testing of the OTP memory 2000 by using the test column 2220 may be merged. That is, when the OTP memory 2000 is determined to be normal as a result of testing the OTP memory 2000 by using the test cell array 2300 as illustrated in FIG. 2 or 7, the OTP memory 2000 is determined to be normal, the OTP memory 2000 may be tested using test columns 2220 as illustrated in FIG. 9. That is, before unprogrammed test cells included in the test cell array 2300 or OTP cells included in the test columns 2220 are programmed, the OTP memory device 2000 when it is defective related to the read operation may be detected at an early stage by determining whether reading of mask-programmed test cells included in the test cell array 2300 succeeds. This can result in more efficient testing operation of the OTP memory device 2000, as described herein.

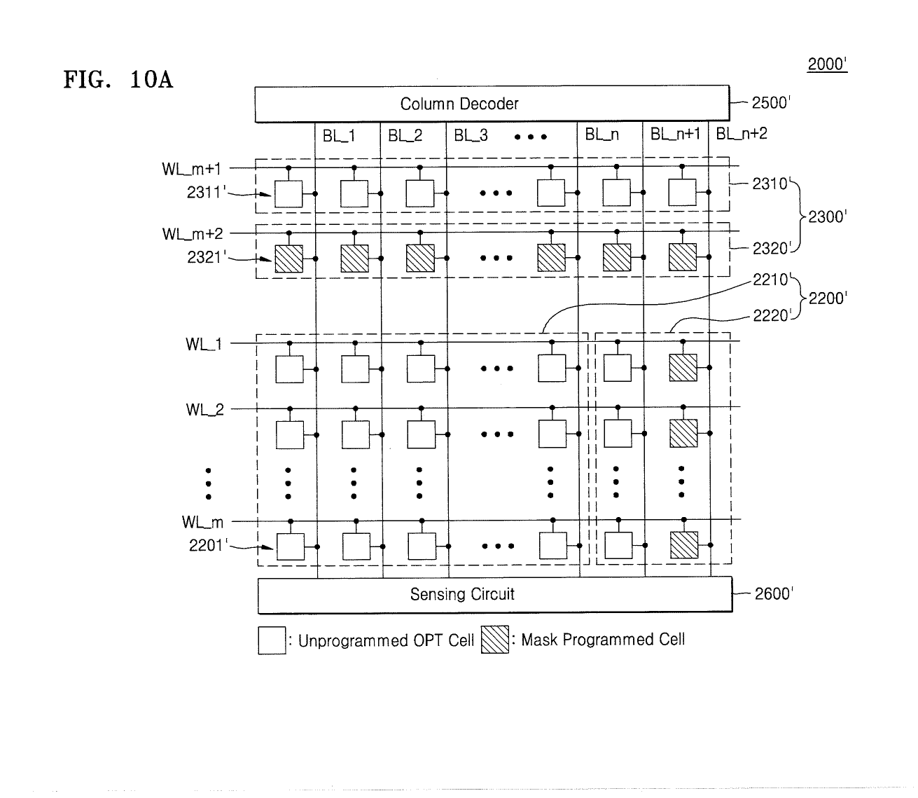

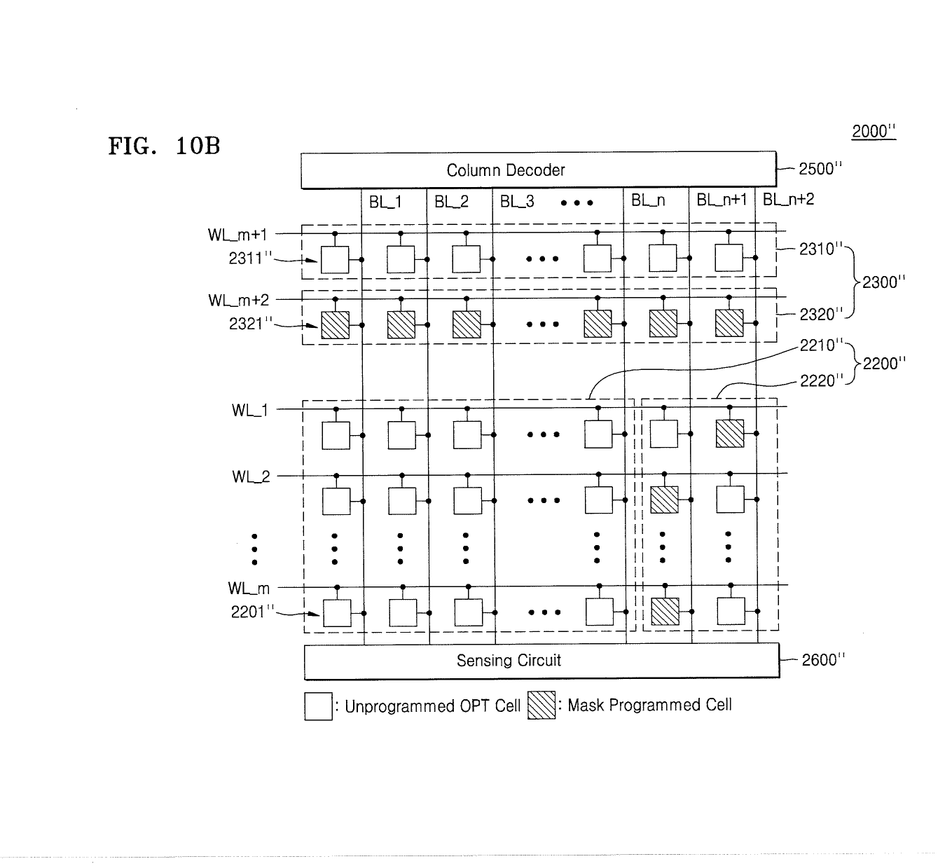

FIGS. 10A and 10B are diagrams illustrating OTP memory devices 2000′ and 2000″ which are examples of the OTP memory device 2000 including programmed test columns, according to exemplary embodiments of the present inventive concepts. As described herein with reference to FIG. 9, the OTP cells included in the test columns 2220 of the OTP cell array 2200 may be programmed and read to test the row driver 2400, the word lines WL_1 to WL_m, a program voltage application path, etc.

According to an exemplary embodiment, OTP cells may be programmed such that OTP cells included in two or more test columns and connected to the same word line store different data. That is, the OTP cells may be programmed to test the row driver 2400, the word lines WL_1 to WL_m, etc. with respect to OTP cells respectively storing ‘0’ and ‘1’.

Referring to FIG. 10A, OTP cells included in the test columns 2220′ may be programmed or unprogrammed so that OTP cells included in one test column are made to store the same data values. For example, OTP cells associated with bit line BLn+1 can be mask programmed to store the data value ‘1’, while OTP cells associated with bit line BLn+2 can be mask programmed to store the data value ‘0’, or vice-versa. Also, referring to FIG. 10B, OTP cells included in the test columns 2220″ may be programmed or unprogrammed so that OTP cells included in one test column are not made to store the same data values. For example, OTP cells of the same bit line association BLn+1, BLn+2 but different word line association WL_1, WL_2 can be programmed to have different data values, as shown.

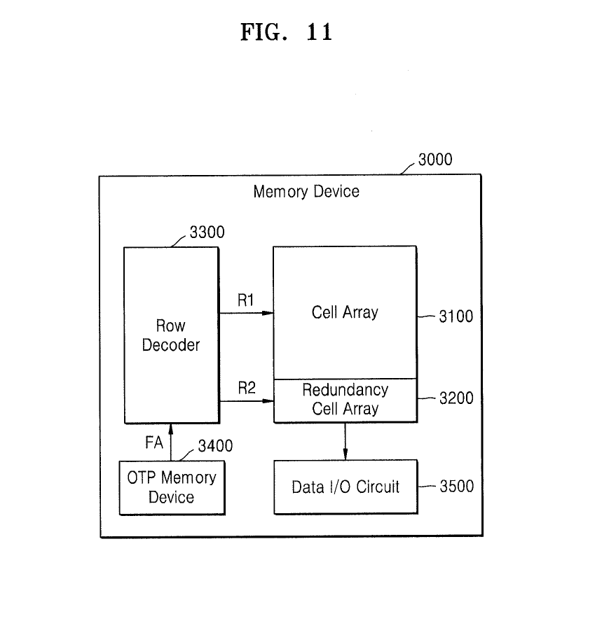

FIG. 11 is a block diagram of a memory device 3000 including an OTP memory device 3400 according to an exemplary embodiment. According to an exemplary embodiment, the OTP memory device 3400 may be included in the memory device 3000, and store information regarding defective memory cells of the memory device 3000 in a nonvolatile manner. Referring to FIG. 11, the memory device 3000 may include a cell array 3100, a redundancy cell array 3200, a row decoder 3300, the OTP memory device 3400, and a data input/output (I/O) circuit 3500.

The cell array 3100 and the redundancy cell array 3200 may include a plurality of memory cells. As a non-limiting example, the memory device 3000 may be a volatile memory device, e.g., a dynamic random access memory (DRAM), a static RAM (SRAM), a mobile DRAM, a double data rate synchronous DRM (DDR SDRAM), a low-power DDR (LPDDR) SDRAM, a graphic DDR (GDDR), a Rambus DRAM (RDRAM), etc. The cell array 3100 and the redundancy cell array 3200 may include a plurality of volatile memory cells. Alternatively, as a non-limiting example, the memory device 3000 may be a nonvolatile memory device, e.g., an electrically erasable programmable read-only memory (EEPROM), a flash memory, a phase-change RAM (PRAM), a resistance RAM (RRAM), a nano floating gate memory (NFGM), a polymer RAM (PoRAM), a magnetic RAM (MRAM), a ferroelectric RAM (FRAM), etc. The cell array 3100 and the redundancy cell array 3200 may include a plurality of nonvolatile memory cells.

The cell array 3100 may include a defective memory cell which data cannot be written to or read from normally due to a process of manufacturing the memory device 3000. The memory device 3000 may store information regarding the defective memory cell in the OTP memory 3400, so that the defective memory cell may be replaced with a memory cell included in the redundancy cell array 3200. Thus, the memory device 3000 may be prevented from being discarded due to the determined presence of the defective memory cell.

The row decoder 3300 may receive a signal FA indicating the location of the defective memory cell in the cell array 3100 from the OTP memory 3400, generate a first or second row signal on the basis of an address signal received from a source external to the memory device 3000 and the signal FA output from the OTP memory 3400, and transmit the first or second row signal to the cell array 3100 or the redundancy cell array 3200. For example, when the received address signal and the signal FA output from the OTP memory 3400 are identical to each other, the row decoder 3300 may generate the second row signal and transmit it to the redundancy cell array 3200, and a signal corresponding to data stored in a memory cell included in the redundancy cell array 3200 may be transmitted to the data I/O circuit 3500.

The data I/O circuit 3500 may sense signals output from the cell array 3100 and the redundancy cell array 3200 via bit lines or supply a signal to bit lines so as to write data received from the external source to memory cells included in the cell array 3100 and the redundancy cell array 3200.

The OTP memory device 3400 may include a test cell array and may further include a test column as described above. Since a time required to test the OTP memory device 3400 may be reduced and the OTP memory 3400 determined to be normal as a result of testing the OTP memory device 3400 is available to a user, the productivity of the memory device 3000 including the OTP memory device 3400 may be improved.

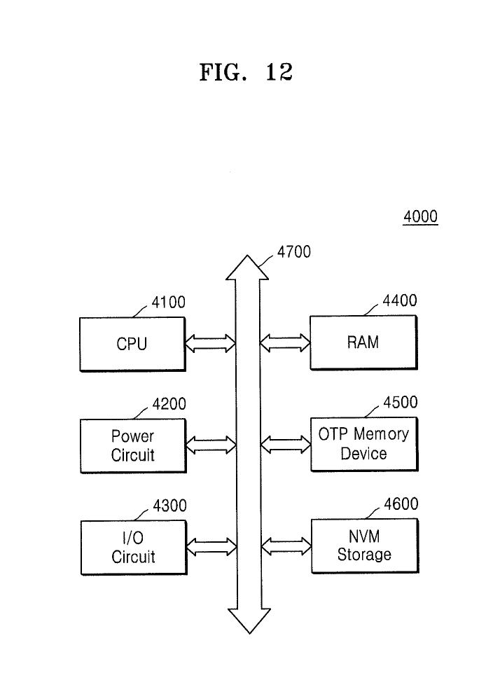

FIG. 12 is a block diagram of a computing system 4000 including an OTP memory device 4500 according to an exemplary embodiment. As illustrated in FIG. 12, the computing system 4000 may include a central processing unit (CPU) 4100, a power circuit 4200, an I/O circuit 4300, a RAM 4400, an OTP memory device 4500, and a nonvolatile storage device 4600. The elements of the computing system 4000 may be connected via a system bus 4700 and communicate with one another via the system bus 4700. Although not shown in FIG. 12, the computing system 4000 may further include ports for communicating with a video card, a sound card, a memory card, a universal serial bus (USB) device, etc. or other electronic devices.

The CPU 4100 may perform particular calculations or tasks and control an operation of the computing system 4000. For example, the CPU 4100 may be a micro-processor, a graphic processing unit (CPU), or the like. The CPU 4100 may be connected to an expansion bus such as a peripheral component interconnect (PCI) bus.

The power circuit 4200 may manage power to be supplied to the computing system 4000. The I/O circuit 4300 may support communication with the outside of the computing system 4000, e.g., a user or another electronic device.

The RAM 4400 may store data needed to operate the computing system 4000. For example, the RAM 4400 may support direct memory access (DMA), etc. to store data received from the system bus 4700 or to transmit stored data to the system bus 4700. Also, the RAM 4400 may function as a data memory of the CPU 4100. The nonvolatile storage device 4600 may retain data stored therein even when power supply cuts off, store a program including commands to be processed by the CPU 4100, and store data (e.g., multimedia data) processed by the CPU 4100.

The OTP memory device 4500 may store information regarding attributes of the computing system 4000 and booting code to be executed by the CPU 4100. As described above, the OTP memory device 4500 may include a test cell array and may further include a test column. A time required to test the OTP memory device 4500 may be reduced, and the OTP memory 4500 when is determined to be normal as a result of testing the OTP memory device 4500 is available to a user. In particular, when the computing system 4000 is embodied as a SoC, the productivity of the computing system 4000 including the OTP memory 4500 may be improved.

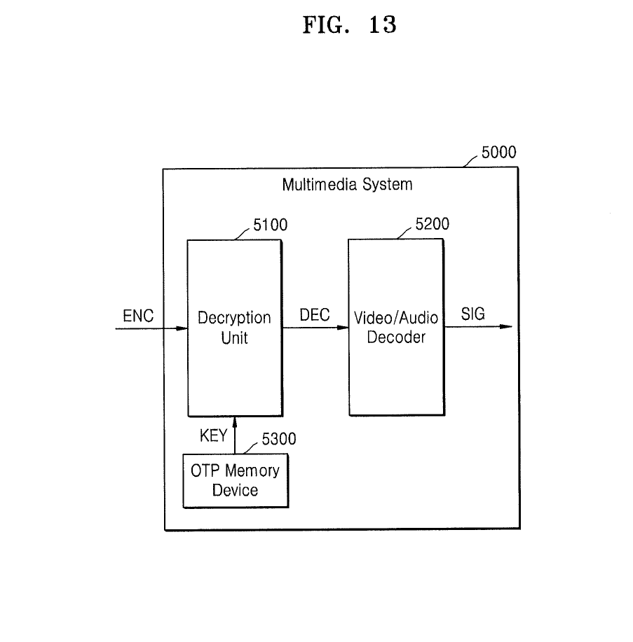

FIG. 13 is a block diagram of a multimedia system 5000 according to an exemplary embodiment. As illustrated in FIG. 13, the multimedia system 5000 such as a smart television (TV) or a setup box may include a decryption unit 5100, a video/audio decoder 5200, and an OTP memory device 5300.

The decryption unit 5100 may decrypt an encrypted signal ENC and output a decrypted signal DEC. The video/audio decoder 5200 may output a multimedia signal SIG by decoding the decrypted signal DEC corresponding to compressed data.

According to an exemplary embodiment, the OTP memory device 5300 may store and output a decryption key KEY to be used for the encryption unit 5100 to decrypt the encrypted signal ENC. The decryption key KEY may be programmed in the OTP memory device 5300 during manufacture of the multimedia system 5000, and protected from unpermitted access from the outside.

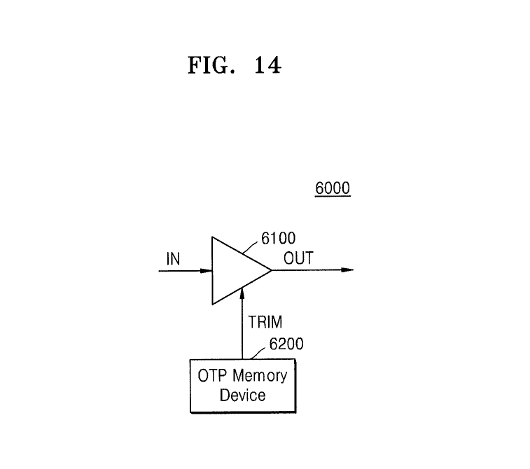

FIG. 14 is a block diagram of a system 6000 including an OTP memory device 6200 according to an exemplary embodiment. As illustrated in FIG. 14, the system 6000 may include a signal processing block 6100 which generate an output signal OUT by processing an input signal IN, e.g., amplifying or converting the input signal IN. The input signal IN and/or the output signal OUT may be analog signals.

According to an exemplary embodiment, the OTP memory device 6200 may store data corresponding to information needed to process an analog signal. For example, the OTP memory 6200 may store offset information, gain information, etc. of an analog signal according to unique characteristics of the signal processing block 6100 on the basis of a result of testing the system 6000.

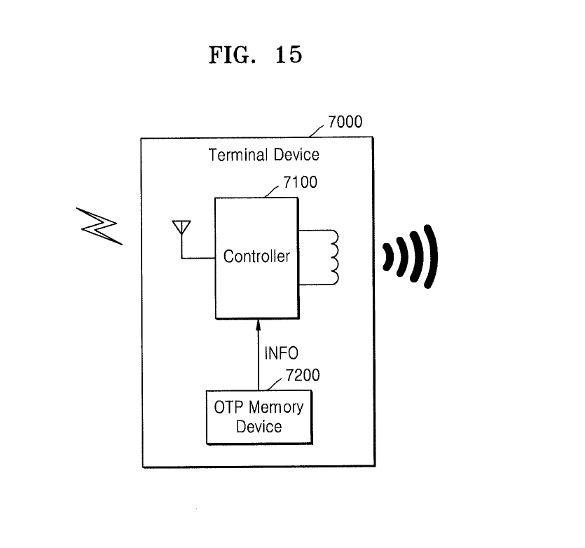

FIG. 15 is a block diagram of a terminal device 7000 including an OTP memory device 7200 according to an exemplary embodiment. As illustrated in FIG. 15, the terminal device 7000 may include a controller 7100, an OTP memory 7200, and antennae. The antennae may generate or receive a signal for wireless mobile communication, such as long-term evolution (LTE), or short-range wireless communication, such as near field communication (NFC) and Bluetooth, under control of the controller 7100.

According to an exemplary embodiment, the OTP memory device 7200 may store personal information INFO regarding a user of the terminal device 7000. For example, the OTP memory device 7200 may store payment information, account information, authentication information, healthcare information, etc. of the user. The controller 7100 may transmit the personal information INFO to other electronic devices via the antennae in a secure state. When the controller 7100 and the OTP memory device 7200 are embodied as one chip together, i.e., when they are embodied as an embedded secure element (eSE), the personal information INFO may be protected from unpermitted access from the outside.

Exemplary embodiments have been illustrated and described in the drawings and the detailed description as described above. Although the specific terms are used to explain these embodiments in the present disclosure, the specific terms are not intended to restrict the scope of the inventive concept and are only used for a better understanding of (to facilitate the understanding of) the inventive concept. It will be understood by those of ordinary skill in the art that various changes in form and details may be made without departing from the spirit and scope of the inventive concept as defined by the appended claims. Therefore, the scope of the inventive concepts is defined not by the detailed description of the inventive concepts but rather by the appended claims.

What is claimed is:

1. A one-time programmable (OTP) memory comprising:
an OTP cell array comprising OTP cells which are activated by an address received from a source external to the OTP memory and which OTP cells are unprogrammed; and
a test cell array comprising a first test row having unprogrammed first test cells and a second test row comprising mask-programmed second test cells, and sharing bit lines extending in a column direction with the OTP cell array,
wherein the first test cells and second test cells are accessible during testing of the OTP cell array.

2. The OTP memory of claim 1, wherein the first test cells have a same structure as the OTP cells.

3. The OTP memory of claim 1, wherein the test cell array further comprises a third test row comprising third test cells which are accessible during the testing of the OTP cell array and which are mask-programmed.

4. The OTP memory of claim 3, wherein the second and third test cells connected to a same bit line are mask-programmed to different states.

5. The OTP memory of claim 4, wherein the second test cells are mask-programmed to a state corresponding to programmed OTP cells, and
the third test cells are mask-programmed to a state corresponding to unprogrammed OTP cells.

6. The OTP memory of claim 1, further comprising a sensing circuit configured to sense voltages or currents of the bit lines,
wherein the OTP cell array is located along the bit lines between the test cell array and the sensing circuit.

7. The OTP memory of claim 1, further comprising:
a row decoder configured to apply a read voltage or a program voltage to rows of the OTP cell array and the test cell array; and
a test controller configured to control the row decoder to selectively apply the program voltage to the first test row after the row decoder applies the read voltage to the second test row, during the testing of the OTP cell array.

8. The OTP memory of claim 7, wherein, during the testing of the OTP cell array, the test controller controls the row decoder such that the row decoder applies the program voltage to the rows of the OTP cell array.

9. The OTP memory of claim 8, further comprising a column decoder configured to apply a program allow voltage or a program inhibit voltage to the bit lines,
wherein the test controller controls the column decoder to apply the program allow voltage to at least one bit line of the OTP cell array during the testing of the OTP cell array.

10. The OTP memory of claim 9, wherein the row decoder is located on a first end of the OTP cell array, and
the at least one bit line is connected to OTP cells of a column at a second end of the OTP cell array opposite to the first end.

11. A one-time programmable (OTP) memory comprising:
an OTP cell array comprising OTP cells which are unprogrammed;
a test cell array sharing bit lines extending in a column direction with the OTP cell array, and comprising a first test row having unprogrammed first test cells and a second test row including mask-programmed second test cells, and
a test controller configured to control programming of the first test cells after the second test cells are read normally, during testing of the OTP cell array.

12. The OTP memory of claim 11, wherein the test cell array further comprises a third test row comprising third test cells mask-programmed to a state different than a state of the second test cells, and
wherein, during the testing of the OTP cell array, the test controller controls programming of the first test cells after the second and third test cells are read normally.

13. The OTP memory of claim 12, further comprising a sensing circuit configured to sense voltages or currents of the bit lines,
wherein the OTP cell array is located along the bit lines between the test cell array and the sensing circuit.

14. The OTP memory of claim 11, wherein, during the testing of the OTP cell array, the test controller controls programming and reading of OTP cells connected to at least one bit line of the OTP cell array.

15. The OTP memory of claim 14, further comprising a row decoder configured to apply a read voltage or a program voltage to rows of the OTP cell array, the row decoder being located on a first end of the OTP cell array, and
wherein the at least one bit line is connected to OTP cells of a column at a second end of the OTP cell array opposite to the first end.

16. A one-time-programmable (OTP) memory device, comprising:
an array of unprogrammed OTP cells arranged at intersections of, and connected to, rows of externally addressable word lines and columns of bit lines;
an array of test cells connected to the columns of bit lines that are same as those to which the array of OTP cells are connected, the array of test cells including:
a first sub-array of test cells arranged at intersections of, and connected to, a first internally addressable word line and the same columns of bit lines, the first sub-array of test cells having first unprogrammed test cells; and
a second sub-array of test cells arranged at intersections of, and connected to, a second internally addressable word line and the same columns of bit lines, the second sub-array of test cells having second mask-programmed test cells; and
a test controller that first performs a read operation of the second sub-array of test cells, and, in the event the read operation is successful, next performs a programming operation of the first sub-array of test cells,
wherein the first and second internally addressable word lines are inaccessible by an externally applied address of the OTP cells.

17. The OTP memory device of claim 16,
wherein the array of test cells further comprises: a third sub-array of test cells arranged at intersections of, and connected to, a third internally addressable word line and the same columns of bit lines, the third sub-array of test cells having third mask-programmed test cells, and
wherein the test controller first performs a first read operation of the second sub-array of test cells, and, in the event the first read operation is successful, next performs a second read operation of the third sub-array of test cells, and, in the event the second read operation is successful, next performs a programming operation of the first sub-array of test cells, and
wherein the first, second and third internally addressable word lines are inaccessible by an externally applied address of the OTP cells.

18. The OTP memory device of claim 17 wherein the third sub-array of mask-programmed test cells and the second sub-array of mask-programmed test cells are mask-programmed to have different data values.

19. The OTP memory device of claim 16, further comprising a sensing circuit connected to the same columns of bit lines and configured to sense voltages or currents of the bit lines, and wherein the array of unprogrammed OTP cells is positioned along the bit lines between the array of test cells and the sensing circuit.

20. The OTP memory device of claim 16, further comprising:
at least one test bit line; and
at least one bit line test cell, the at least one lit line test cell connected to the at least one test bit line and connected to at least one of the externally addressable word lines, and not connected to same bit lines as those to which the array of OTP cells are connected.
